(19) United States
(12) Patent Application Publication
(10) Pub. No.: US 2024/0213407 A1
(43) Pub. Date: Jun. 27, 2024

(54) LIGHT-EMITTING DIODE CHIP AND LIGHT-EMITTING DEVICE

(71) Applicant: QUANZHOU SANAN SEMICONDUCTOR TECHNOLOGY CO., LTD., Quanzhou (CN)

(72) Inventors: Weiping XIONG, Quanzhou (CN); Zhiwei WU, Quanzhou (CN); Di GAO, Quanzhou (CN); Huanshao KUO, Quanzhou (CN); Yuren PENG, Quanzhou (CN); Shutian QIU, Quanzhou (CN)

(21) Appl. No.: 18/513,570

(22) Filed: Nov. 19, 2023

(30) Foreign Application Priority Data
Dec. 22, 2022 (CN) 2022116548241

(51) Int. Cl. H01L 33/30; H01L 33/02; H01L 33/22; H01L 33/62

(52) U.S. Cl. CPC H01L 33/305; H01L 33/025; H01L 33/22; H01L 33/62

(57) ABSTRACT

A light-emitting diode (LED) chip includes a semiconductor laminated layer including a first semiconductor layer, a light-emitting layer and a second semiconductor layer arranged from bottom to top, a transparent conductive layer disposed on the semiconductor laminated layer, a transparent bonding layer disposed on the transparent conductive layer, and a transparent substrate disposed on the transparent bonding layer. The second semiconductor layer includes a first sublayer and a second sublayer disposed on a part of an upper surface of the first sublayer, and a doping concentration of the first sublayer is lower than that of the second sublayer. The transparent conductive layer is in contact with an upper surface of the second sublayer and a part of the upper surface of the first sublayer around the second sublayer. The LED chip can improve the manufacturing yield and ensure the ohmic contact and uniform lateral current spreading.

### TECHNICAL FIELD

The disclosure relates to the field of semiconductor optoelectronic devices and technologies, and more particularly to a light-emitting diode (LED) chip and a light-emitting device.

### BACKGROUND

Flip-chip light-emitting diodes (LEDs) are an effective technical means to further improve the luminous efficiency of LEDs due to their advantages of no wire bonding, no electrode shading, and excellent heat dissipation. At present, aluminum gallium indium phosphide (AlGaInP) quaternary materials used for manufacturing high-power and high-brightness red and yellow LEDs mainly use light-absorbing gallium arsenic (GaAs) substrate materials, epitaxial layers are successively grown on a N-type GaAs substrate, and the epitaxial layers include an N-type GaAs buffer layer, an N-type AlGaInP electron injection layer, an undoped AlGaInP light-emitting layer, a P-type AlGaInP hole injection layer and a P-type gallium phosphide (GaP) window layer; a transparent bonding layer, such as a silicon oxide layer, is grown on a side of the P-type GaP window layer; a surface of the transparent bonding layer is bonded with a surface of a transparent substrate, such as sapphire, by a bonding process; then the GaAs substrate material is removed to expose the N-type AlGaInP electron injection layer; and N and P electrodes are respectively formed on the N-type AlGaInP electron injection layer and the P-type window layer. Through the above steps, a flip-chip LED chip with high brightness can be made, and the light can be effectively extracted through a surface and sidewalls of the transparent substrate, thus improving the external quantum efficiency. The obtained flip-chip LED chip is shown in FIG. 1, including a transparent substrate 001, a transparent bonding layer 002, a transparent conductive layer 003, a second semiconductor layer 004, a light-emitting layer 005 and a first semiconductor layer 006. The second semiconductor layer 004 includes a P-type AlGaInP hole injection layer and a P-type GaP window layer, and the first semiconductor layer 006 includes an N-type AlGaInP electron injection layer.

Because of wide band gap, oxidation resistance and good transparency of GaP, a GaP layer is suitable for a window layer, which is used for current spreading and light emission. And in order to improve the light extraction effect, a light-emitting surface of the GaP layer needs to be roughened.

A thickness of the second semiconductor layer in the related art is in a range of 10 micrometer (μm) to 15 μm, and a thickness of the GaP window layer is usually in a range of 6 μm to 10 μm. The thicker thickness of the GaP window layer can allow its surface to form roughened structures and ensure effects of the ohmic contact and the current spreading. However, due to a large lattice difference between the GaP window layer and the GaAs substrate, it is difficult to ensure the crystal growth quality when growing the GaP layer with the thicker thickness, and after bonding, the GaP layer is easy to cause wafer warping, resulting in high bonding failure rate and high chip breakage rate during cutting.

### SUMMARY

The disclosure provides a LED chip with better performance, aiming at reducing a thickness of a semiconductor layer and a degree of wafer warping caused by a lattice difference in a manufacturing process, thereby reducing a bonding failure rate caused by the wafer warping, and also reducing the chip breakage rate during cutting, thereby improving the manufacturing yield. At the same time, the LED chip can ensure good ohmic contact and uniform lateral current spreading.

The disclosure provides a LED chip, including a semiconductor laminated layer, a transparent conductive layer disposed on the semiconductor laminated layer, a transparent bonding layer disposed on the transparent conductive layer, and a transparent substrate disposed on the transparent bonding layer; the semiconductor laminated layer includes a first semiconductor layer, a light-emitting layer, and a second semiconductor layer; the second semiconductor layer includes a first sublayer and a second sublayer, the second sublayer is disposed on a part of an upper surface of the first sublayer, and a doping concentration of the first sublayer is lower than that of the second sublayer; and the transparent conductive layer is in contact with an upper surface of the second sublayer and a part of the upper surface of the first sublayer around the second sublayer.

In an embodiment, a thickness of the second semiconductor layer is 7 μm or less.

In an embodiment, a thickness of the second sublayer is within 1 μm.

In an embodiment, the first sublayer and the second sublayer are made of a same material, the second sublayer includes a GaP layer, and the first sublayer includes a GaP layer.

In an embodiment, a thickness of the GaP layer of the first sublayer is in a range of 0.5 μm to 2 μm, and a doping element of the first sublayer is magnesium (Mg).

In an embodiment, the upper surface of the first sublayer around the second sublayer is a roughened surface, and a roughness of the roughened surface is in a range of 0.1 μm to 1 μm; and an upper surface of the second sublayer is flatter than the upper surface of the first sublayer.

In an embodiment, a doping type of the second semiconductor layer is P-type.

In an embodiment, a doping concentration of the first sublayer is in a range of 1E17 atomic numbers per cubic meter (atoms/cm³) to 5E18 atoms/cm³.

In an embodiment, a doping concentration of the second sublayer is at least 1E19 atoms/cm ³, and a doping element of the second sublayer is carbon (C).

In an embodiment, the second sublayer includes multiple independent protrusion structures formed on the first sublayer, or the second sublayer includes a net structure formed on the first sublayer, or the second sublayer includes multiple strip structures formed on the first sublayer.

In an embodiment, a ratio of a horizontal projection area of the second sublayer to a horizontal projection area of the first sublayer is in a range of 5% to 30%.

In an embodiment, the LED chip is a flip-chip LED chip and includes a first electrode and a second electrode, the first electrode is in contact with the first semiconductor layer and the second electrode is in contact with the transparent conductive layer.

In an embodiment, the transparent conductive layer is made of a transparent metal oxide, and a thickness of the transparent conductive layer is in a range of 20 nanometers (nm) to 1 μm.

In an embodiment, the transparent bonding layer is made of silicon oxide or a combination of aluminum oxide and silicon oxide; and the transparent substrate is a sapphire substrate.

In an embodiment, the first sublayer is a AlGaInP layer or a aluminum indium phosphide (AlInP) layer, and the second sublayer is a AlGaInP layer or a AlInP layer.

The disclosure further provides a light-emitting device including the LED chip described above.

Other features and advantages of the disclosure will be set forth in the subsequent specification, and in part will be apparent from the specification, or may be learned by practice of the disclosure. The purpose and other advantages of the disclosure can be realized and obtained by the structure particularly pointed out in the specification, the claims and the accompanying drawings.

### BRIEF DESCRIPTION OF DRAWINGS

The accompanying drawings are used to provide a further understanding of the disclosure and form a part of the specification. Together with the embodiments of the disclosure, they are used to explain the disclosure and do not constitute a limitation of the disclosure. In addition, the attached data is a descriptive summary, not drawn to scale.

FIG. 1 illustrates a schematic cross-sectional diagram of a flip-chip LED chip in the related art.

FIG. 2 illustrates a schematic cross-sectional diagram of a flip-chip LED chip according to an embodiment 1 of the disclosure.

FIG. 3 illustrates a schematic diagram of a first sublayer and a second sublayer of the flip-chip LED chip according to the embodiment 1 of the disclosure.

FIG. 4 illustrates a schematic diagram of a first sublayer and another second sublayer of the flip-chip LED chip according to the embodiment 1 of the disclosure.

FIG. 5 illustrates a schematic cross-sectional diagram of a flip-chip LED chip according to an embodiment 2 of the disclosure.

FIG. 6 illustrates a schematic cross-sectional diagram of a light-emitting device according to an embodiment 3 of the disclosure.

Description of reference numerals: 001: transparent substrate; 002: transparent bonding layer; 003: transparent conductive layer; 004: second semiconductor layer; 0040: hole injection layer; 0041: first sublayer; 0042: second sublayer; 005: light-emitting layer; 006: first semiconductor layer; 007: first electrode; 008: second electrode; 009: insulation layer; 010: first pad; 011: second pad; 012: metal connection layer; 013: substrate.

### DETAILED DESCRIPTION OF EMBODIMENTS

The implementation of the disclosure is described below through specific embodiments, and those skilled in the art can easily understand other advantages and effects of the disclosure from the contents disclosed in this specification. The disclosure can also be implemented or applied by other different specific embodiments, and various details in this specification can be modified or changed based on different viewpoints and applications without departing from the spirit of the disclosure.

It should be noted that the drawings provided in the embodiments only illustrate the basic idea of the disclosure in a schematic way, so only the components related to the disclosure are shown in the drawings instead of being drawn according to the number, shape and size of components in actual implementation, and the type, quantity and proportion of the components in actual implementation can be changed at will, and the layout of the components may be more complicated.

In the following, the implementation of the disclosure will be described in detail with the attached drawings and embodiments, so as to fully understand and implement the implementation process of how to apply technical means to solve the technical problem and achieve the technical effects.

### Embodiment 1

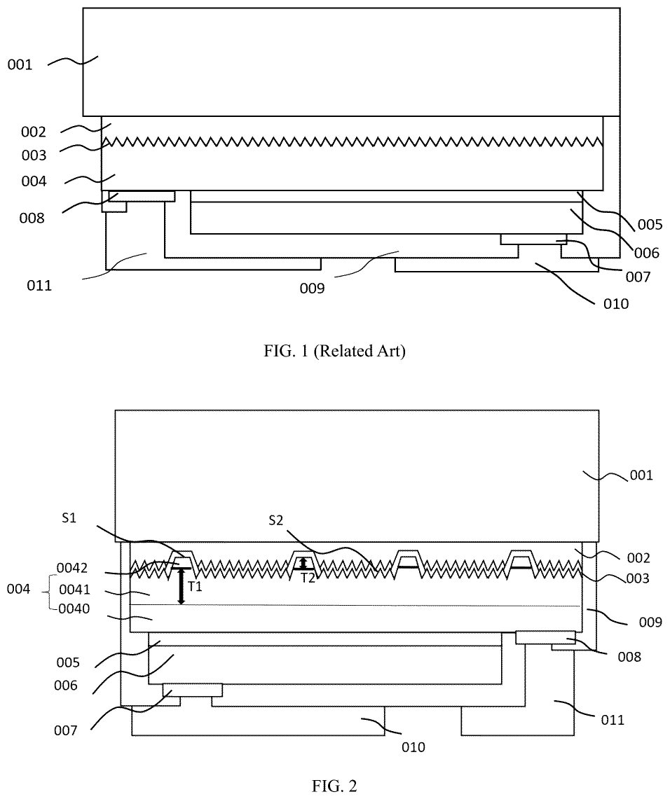

FIG. 2 illustrates a schematic cross-sectional diagram of a flip-chip LED chip. Specifically, the flip-chip LED chip includes a transparent substrate 001, a transparent bonding layer 002, a transparent conductive layer 003 and a semiconductor laminated layer. The semiconductor laminated layer includes a second semiconductor layer 004, a light-emitting layer 005, and a first semiconductor layer 006.

The first semiconductor layer 006 and the second semiconductor layer 004 have different conductive states, electrical properties, polarity, or at least provide electrons or holes depending on different doping elements. The light-emitting layer 005 is formed between the first semiconductor layer 006 and the second semiconductor layer 004, and can convert electrical energy into light energy. The wavelength of the emitted light is adjusted by changing the physical and chemical composition of one or more of layers of the semiconductor laminated layer. The semiconductor laminated layer is mainly aluminum gallium indium phosphide (AlₓGa₁₋ₓInP; 0≤×≤1) series layer. The light-emitting layer 005 can be a single heterostructure (SH), a double heterostructure (DH), a double-sided double heterostructure (DDH), or a multi-quantum well (MWQ). Specifically, the light-emitting layer 005 can be a neutral, P-type, or N-type electrical semiconductor. When a current is applied to pass through the semiconductor laminated layer, the light-emitting layer 005 emits light. When the material of the light-emitting layer 005 is the aluminum indium gallium phosphide (AlₓGa₁₋ₓInP; 0≤×≤1) series, it emits red, orange, yellow, and infrared light.

In this embodiment, the material of the light-emitting layer of the semiconductor laminated layer is the aluminum gallium indium phosphide (AlₓGa₁₋ₓInP; 0≤×≤1) series, and the emitted light is red. The first semiconductor layer 006 is the N-type semiconductor layer, and the second semiconductor layer 004 is the P-type semiconductor layer, and the semiconductor laminated layer at least has a hole injection layer and an electron injection layer.

The second semiconductor layer 004 includes a first sublayer 0041 and a second sublayer 0042 disposed on a part of an upper surface of the first sublayer 0042. A doping concentration of the first sublayer 0041 is lower than that of the second sublayer 0042, an upper surface of the second sublayer 0042 provides an ohmic contact region S1, a part of the first sublayer 0041 around the second sublayer 0042 provides a current spreading region S2, and the first sublayer 0041 is in contact with the second sublayer 0042. The transparent conductive layer 003 covers the ohmic contact region S1 and the current spreading region S2, and forms a relatively low contact resistance with the upper surface of the second sublayer 0042 to form an ohmic contact, thereby realizing current injection, and forms a relatively high contact resistance with the current spreading region S2 to block current injection.

In some embodiments, a thickness T2 of the second sublayer 0042 is within 1 μm, more preferably within 500 nm. For example, the thickness of the second sublayer 0042 is in a range of 50 nm to 300 nm.

In some embodiments, the second sublayer 0042 is a GaP layer, and a doping concentration of the second sublayer 0042 is at least 1E19 atoms/cm³, for example, the second sublayer 0042 is doped with C, and more preferably, the doping concentration of the second sublayer 0042 is in a range of 1E19 atoms/cm³ to 1E20 atoms/cm³.

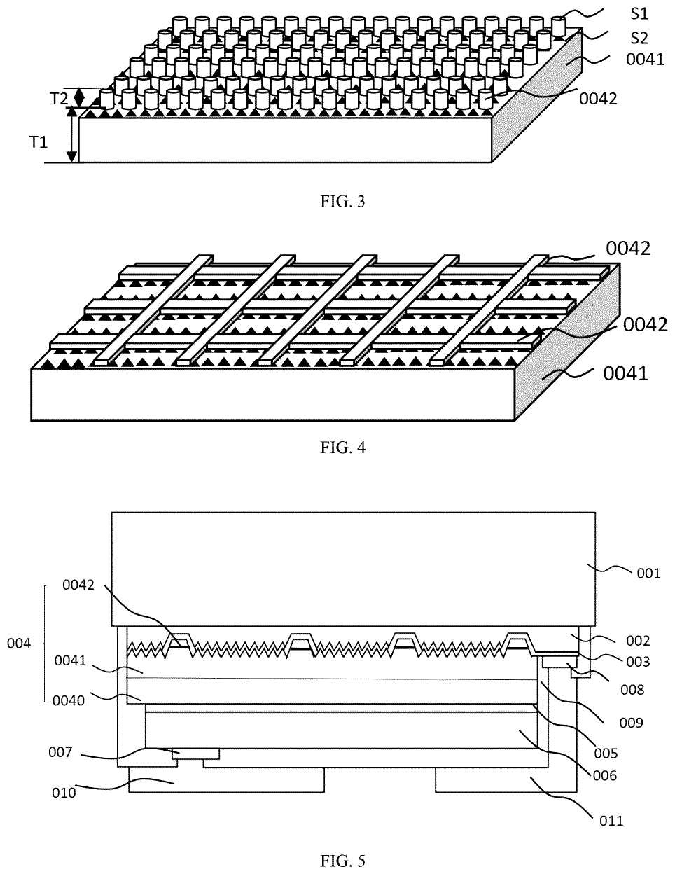

In some embodiments, as shown in FIG. 3, the second sublayer 0042 is disposed on the first sublayer 0041 and includes multiple independent protrusion structures relative to the upper surface of the first sublayer 0041. Upper surfaces of the multiple independent protrusion structures, that is, the ohmic contact region S1, are circular, square, or another polygon or ellipse that is not square. A sum of horizontal projection areas of the upper surfaces of the multiple independent protrusion structures accounts for 5-30% of a horizontal projection area of the upper surface of the whole first sublayer 0041. A width of the upper surface of each protrusion structure can be in a range of 1 μm to 50 μm, for example, in a range of 5 μm to 20 μm, and a distance between independent protrusion structures (i.e., adjacent two protrusion structures) is greater than a width of the upper surface of the protrusion structure. Preferably, the protrusion structure has a inclined side wall, and the inclined side wall has an inclination angle greater than 90 degrees (°) relative to the upper surface of the protrusion structure, the inclination angle is, such as in a range of 100° to 170°, or more preferably in a range of 120° to 150°.

In some embodiments, as shown in FIG. 4, the second sublayer 0042 is disposed on the first sublayer 0041 and includes a net structure, the net structure includes multiple intersecting strip structures. An upper surface of the net structure is the ohmic contact region S1, a horizontal projection area of the upper surface of the net structure accounts for 5-30% of the horizontal projection area of the upper surface of the first sublayer 0041. The net structure has an inclined side wall (i.e., each strip structure of the net structure has the inclined side wall), which has an inclination angle greater than 90° relative to the upper surface of the net structure (i.e., upper surface of each strip structure of the net structure), the inclination angle is, such as in a range of 100° to 170°, or more preferably in a range of 120° to 150°. A width of an upper surface on each strip structure of the net structure can be in a range of 1 μm to 50 μm, such as in a range of 5 μm to 20 μm.

In some embodiments, the second sublayer 0042 is disposed on the first sublayer 0041 and include multiple strip structures (not shown in the figure), and a sum of horizontal projection areas of upper surfaces of the multiple strip structures, that is, the ohmic contact region S1, accounts for 5-30% of the horizontal projection area of the upper surface of the first sublayer 0041. Each strip structure has an inclined side wall, and the inclined side wall has an inclination angle greater than 90° relative to the upper surface of the strip structure. For example, the inclination angle is in a range of 100° to 170°, or more preferably in a range of 120° to 150°. The multiple strip structures are disposed on the first sublayer 0041 in parallel, thereby ensuring the uniform distribution of the ohmic contact region and the current spreading region of the current. The width of the upper surface of each strip structure can be in a range of 1 μm to 50 μm, for example, in a range of 5 μm to 20 μm, and a distance between adjacent two strip structures is greater than the width of the upper surface of the single strip structure.

Compared with the net structure and the strip structure, according to the distribution characteristics of the multiple protrusion structures of the second sublayer 0042, the second sublayer 0042 set as the multiple protrusion structures is more conducive to spread the current and promote the uniform distribution of current.

A part of the upper surface of the first sublayer 0041 is in contact with the transparent conductive layer 003, and the first sublayer 0041 is a part of the second semiconductor layer 004. In some embodiments, as shown in FIGS. 3 and 4, the part of the upper surface of the first sublayer 0041 around the second sublayer 0042 has roughened structures, and the first sublayer 0041 is a layer for forming the roughened structures. In some embodiments, roughness (an average height of the roughened structures) of the part of the upper surface of the first sublayer 0041 around the second sublayer 0042 is in a range of 0.1 μm to 1 μm, and the roughened structures are beneficial to light emission, more preferably, the roughness is in a range of 100 nm to 600 nm.

In some embodiments, in order to form the roughened structures, a thickness T1 of the first sublayer 0041 of the second semiconductor layer 004 has a sufficient thickness, which is greater than the thickness T2 of the second sublayer 0042.

In some embodiments, the first sublayer 0041 is a GaP layer for forming the roughened structures, and compared with the material of AlGaInP series containing aluminum, the GaP layer has the advantage of good light transmission effect, a maximum thickness of the GaP layer of the first sublayer 0041 is at least 500 nm (including the average height of the roughened structures), and the maximum thickness is at most 4 μm. Preferably, the maximum thickness of the GaP layer of the first sublayer 0041 is at most 2 μm, and too thick of the thickness of the GaP layer will cause the crystal quality to decrease and warpage. The GaP layer of the first sublayer 0041 can also assist current spreading and promote the uniformity of current distribution. Preferably, a doping concentration of the GaP layer included in the first sublayer 0041 is in a range of 1E17 atoms/cm³ to 5E18 atoms/cm³.

In some embodiments, both the first sublayer 0041 and the second sublayer 0042 are the same material layer, for example, the second sublayer 0042 is also a GaP layer, which can prevent the lattice difference between the first sublayer 0041 and the second sublayer 0042, improve the crystal quality, and ensure the ohmic contact effect and the roughening effect.

In some embodiments, a doping element of the first sublayer 0041 is Mg.

As an alternative embodiment, the first sublayer and the second sublayer are both AlGaInP layers or AlInP layers, and canceling the use of the GaP layer in the semiconductor laminated layer can reduce the warping degree of the semiconductor laminated layer, thus improving the manufacturing yield.

The second semiconductor layer 004 further includes at least a hole injection layer 0040, which is closer to the light-emitting layer 005 than the first sublayer 0041. The hole injection layer 0040 is an AlGaInP layer or an AlInP layer. A doping concentration of the hole injection layer 0040 is in a range of 1E17 atoms/cm³ to 5E18 atoms/cm³, and a doping element of the hole injection layer 0040 is Mg. Preferably, the doping concentration of the hole injection layer 0040 is lower than or equal to the doping concentration of the first sublayer 0041.

In some embodiments, the first sublayer 0041 and the hole injection layer 0040 are made of the same material, both of which are AlGaInP layers or AlInP layers.

In some embodiments, a thickness of the second semiconductor layer 004 is less than 7 μm, such as in a range of 3 μm to 6 μm.

In some embodiments, the upper surface of the second sublayer 0042 is flat, without roughened or graphical structures, to ensure a good ohmic contact effect between the transparent conductive layer and the upper surface of the second sublayer. The upper surface of the second sublayer 0042 is flatter than the part of the upper surface of the first sublayer 0041 around the second sublayer 0042.

The transparent conductive layer 003 is disposed on the second semiconductor layer 004, and in contact with the upper surface of the second sublayer 0042 of the second semiconductor layer 004 and the part of the upper surface of the first sublayer 0041 around the second sublayer 0042.

An ohmic contact is formed between the surface of the transparent conductive layer 003 and the second sublayer 0042, and the transparent conductive layer 003 covers the upper surface of the first sublayer 0041, enabling the lateral transmission of current, thereby reducing the design thickness of the current spreading layer, i.e., the GaP layer, in the traditional second semiconductor layer.

The transparent conductive layer 003 is made of a metal oxide, such as indium tin oxide (ITO), indium oxide (InO), tin oxide (SnO), cadmium tin oxide (CTO), antimony tin oxide (ATO), zinc aluminum oxide (AZO), zinc tin oxide (ZTO), or zinc oxide (ZnO).

In some embodiments, a thickness of the transparent conductive layer 003 is in a range of 20 nm to 1 μm, such as in a range of 60 nm to 300 nm.

The first semiconductor layer 006 includes an electron injection layer, a current spreading layer, and an ohmic contact layer (not shown in detail in the figure). Each of the electron injection layer and the current spreading layer can be an AlInP layer or an AlGaInP layer (not shown in the figure), and the ohmic contact layer can be an AlInP layer, an AlGaInP layer or a gallium arsenide layer. The electron injection layer is closer to the light-emitting layer than the current spreading layer, and the current spreading layer is closer to the light-emitting layer than the ohmic contact layer. Preferably, the thickness of the first semiconductor layer 004 is in a range of 2 μm to 4 μm, and the thickness of the light-emitting layer is in a range of 100 nm to 1000 nm.

The transparent bonding layer 002 is covered on the transparent conductive layer 003, and the transparent substrate 001 is disposed on the transparent bonding layer 002. The transparent substrate 001 is adhered to the second semiconductor layer 003 through the transparent bonding layer 002. The light emitted by the light-emitting layer 005 can penetrate the transparent bonding layer 002 and the transparent substrate 001, and radiate from the upper surface and side walls of the transparent substrate 001. The material of the transparent bonding layer 002 is transparent to the light emitted by the light-emitting layer 005, including an organic material such as Su8, benzocyclobutene (BCB), perfluorocyclobutane (PFCB), epoxy, acrylic resin, cycloolefin copolymer (COC), polymethyl methacrylate (PMMA), polyethylene terephthalate (PET), polycarbonate (PC), polyetherimide, or fluorocarbon polymer. Alternatively, the material of the transparent bonding layer 002 may include an inorganic material such as silicone or glass, or an inorganic insulation material such as aluminum oxide (Al₂O₃), silicon nitride (SiNₓ), silicon dioxide (SiO₂), titanium oxide (TiO₂), or magnesium fluoride (MgF₂).

In some embodiments, a material made of the transparent bonding layer 002 has a lower refractive index than that of the transparent conductive layer 003, such as silicon oxide or a combination of aluminum oxide and silicon oxide. In this embodiment, the transparent bonding layer 002 is a combination of an aluminum oxide layer and a silicon oxide layer, and the aluminum oxide layer is closer to the transparent conductive layer 003 than the silicon oxide layer.

In some embodiments, a thickness of the transparent bonding layer 002 is in a range of 1 μm to 4 μm.

The material of the transparent substrate 001 includes a material that is transparent to the light emitted by the light-emitting layer 005, such as gallium arsenide (GaAs), gallium phosphide (GaP), gallium nitride (GaN), sapphire, diamond, glass, quartz, zinc oxide (ZnO), or aluminum nitride (AlN), etc. In this embodiment, the preferred transparent substrate 001 is made of a sapphire material with a thickness of 40-100 μm.

The first electrode 007 is formed on a side of the first semiconductor layer 006, and the second electrode 008 is formed on a side of the second semiconductor layer 004. And the first electrode 007 and the second electrode 008 are disposed on the same side of the semiconductor laminated layer. A surface of the second electrode 008 in contact with the second semiconductor layer 004 forms the ohmic contact, and the second semiconductor layer 004 further includes a high-concentration doping layer (not shown in the figure) that forms the ohmic contact with the second electrode 008. The high-concentration doping layer (not shown in the figure) can be disposed between the hole injection layer and the first sublayer, and the doping concentration, main material, and doping element of the high-concentration doping layer can be the same as the second sublayer.

The materials of the first electrode 007 and the second electrode 008 include metals, such as gold (Au), germanium (Ge), beryllium (Be), nickel (Ni), palladium (Pd), zinc (Zn), or their alloys.

The first electrode 007 and the second electrode 008 at least include metals that form ohmic contacts with the second semiconductor layer 006 and the first semiconductor layer 004, respectively. For example, when the first semiconductor layer 006 is a N-type semiconductor layer, the first electrode 007 includes an ohmic contact metal layer which is an alloy of gold and beryllium; and when the second semiconductor layer 004 is a P-type semiconductor layer, the second electrode 008 includes an ohmic contact metal layer which is an alloy of gold and zinc or an alloy of gold, germanium and nickel, and the ohmic contact metal layer needs to be subjected to a high-temperature fusion process to form an ohmic contact.

An insulation layer 009 covers the surface and the side walls of the semiconductor laminated layer, and partially covers surfaces and side walls of the first electrode 007 and the second electrode 008, and exposes parts of the surfaces of the first electrode 007 and the second electrode 008.

The insulation layer 009 can be a repeating laminated layer of at least one or two different refractive index material layers, such as silicon oxide (SiOₓ) material layer, silicon nitride (SiNₓ) material layer, magnesium fluoride (MgF₂) material layer, etc.

A first pad 010 and a second pad 011 are formed on sides of the first electrode 007 and the second electrode 008 respectively, and formed on a side of the insulation layer 009. The first pad 010 and the second pad 011 are connected to the first electrode 007 and the second electrode 008 respectively.

The first pad 010 and the second pad 011 respectively include titanium (Ti), tungsten (W), platinum (Pt), nickel, tin (Sn), gold or their alloys. The first pad 010 and the second pad 011 can be fixed to a packaging substrate through solder paste.

Through the relevant improvements in this embodiment, the thickness of the semiconductor layer can be reduced, the degree of wafer warping caused by the lattice difference in the manufacturing process can be reduced, the bonding failure rate caused by the wafer warping can be reduced, and the chip breakage rate during the cutting can be reduced, thereby improving the manufacturing yield, while ensuring the ohmic contact and uniform lateral current spreading.

The related design of reducing the thickness of the semiconductor layer in this embodiment ensures the ohmic contact and uniform lateral current spreading, and has nothing to do with the design of the light-emitting surface, so it can be applied not only to flip-chip LED chips, but also to front-mounted LED chips, that is, the side of the semiconductor laminated later facing away from the transparent substrate, i.e., the side of the first pad and the second pad, can be applied to emit light, and the first pad and the second pad can also be designed to be connected to the package substrate by wire bonding.

### Embodiment 2

As an improved implementation of the embodiment 1, as shown in FIG. 5, a flip-chip LED chip of this embodiment includes: a first electrode 007 formed on a side of the first semiconductor layer 006, and a second electrode 008 formed on a side of the transparent conductive layer 003. The second electrode 008 forms an ohmic contact with the transparent conductive layer 003, which can avoid setting a high-concentration doping layer inside the second semiconductor layer 004 for the ohmic contact, avoid light loss caused by the absorption of light by the high-concentration doping layer, and cancel the high-temperature fusion treatment of the second electrode 008 to form an alloy, thus achieving the ohmic contact between the metal layer and the transparent conductive layer.

The transparent conductive layer 003 is made of a metal oxide, such as indium tin oxide (ITO), indium oxide (InO), tin oxide (SnO), cadmium tin oxide (CTO), antimony tin oxide (ATO), zinc aluminum oxide (AZO), zinc tin oxide (ZTO), or zinc oxide (ZnO). In this embodiment, the transparent conductive layer 003 is made of ITO.

In some embodiments, a thickness of the transparent conductive layer 003 is in a range of 20 nm to 1 μm, such as in a range of 60 nm to 300 nm.

The second electrode 008 can include multiple metal layers, each metal layer may be made of one material selected from the group consisting of gold (Au), germanium (Ge), beryllium (Be), nickel (Ni), palladium (Pd), and zinc (Zn); and each metal layer is a layer made of single metal element.

In some embodiments, the transparent conductive layer 003 is in contact with the second semiconductor layer 004, a surface roughness of the first sublayer 0041 is in a range of 0.1 μm to 1 μm. Therefore, a surface of the transparent conductive layer 003 in contact with the first sublayer 0041 also has the same roughness. The transparent conductive layer 003 is further in contact with the second electrode 008, and a surface of the transparent conductive layer 003 in contact with the second electrode 008 is flatter than a surface of the first sublayer 0041 in contact with the transparent conductive layer 003, to ensure good ohmic contact effect.

### Embodiment 3

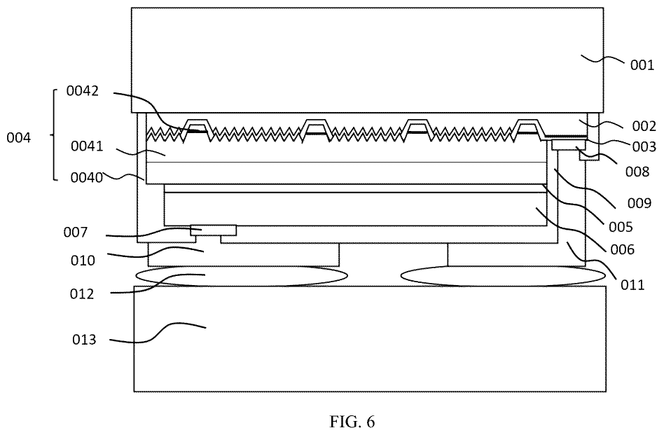

FIG. 6 illustrates a schematic structural diagram of a light-emitting device according to the embodiment 3 of the disclosure. The light-emitting device includes a substrate 013, the flip-chip LED chip of at least one of the aforementioned embodiments is disposed on the substrate 013, and a metal connection layer 012, such as a tin connection layer, is disposed between the substrate 013 and the flip-chip LED chip.

The light-emitting device can but is not limited to the fields of lamps, display screens, etc.

Although the disclosure is described in the context of some exemplary embodiments and usage methods, those skilled in the art should understand that it is not intended to limit the disclosure to these embodiments. On the contrary, it is intended to cover all substitutes, amendments, and equivalents within the spirit and scope of the disclosure as defined in the attached claims.

The embodiments listed in the disclosure are only intended to illustrate the disclosure and are not intended to limit its scope. Any obvious amendments or modifications made by anyone to the disclosure shall not depart from the spirit and scope of the disclosure.

What is claimed is:

1. A light-emitting diode (LED) chip, comprising:
a semiconductor laminated layer comprising a first semiconductor layer, a light-emitting layer, and a second semiconductor layer arranged sequentially from bottom to top;
a transparent conductive layer disposed on the semiconductor laminated layer;
a transparent bonding layer disposed on the transparent conductive layer; and
a transparent substrate disposed on the transparent bonding layer;
wherein the second semiconductor layer comprises a first sublayer and a second sublayer, the second sublayer is disposed on a part of an upper surface of the first sublayer, and a doping concentration of the first sublayer is lower than that of the second sublayer; and
wherein the transparent conductive layer is in contact with an upper surface of the second sublayer and a part of the upper surface of the first sublayer around the second sublayer.

2. The LED chip as claimed in claim 1, wherein a thickness of the second semiconductor layer is less than 7 micrometers (μm).

3. The LED chip as claimed in claim 1, wherein a thickness of the second sublayer is less than 1 μm.

4. The LED chip as claimed in claim 1, wherein the second sublayer and the first sublayer are made of a same material, and the material is one selected from the group consisting of gallium phosphide (GaP), aluminum gallium indium phosphide (AlGaInP) and aluminum indium phosphide (AlInP).

5. The LED chip as claimed in claim 4, wherein the first sublayer comprises a first GaP layer and the second sublayer comprises a second GaP layer.

6. The LED chip as claimed in claim 5, wherein a thickness of the first GaP layer is in a range of 0.5 μm to 2 μm, and a doping element of the first sublayer is magnesium (Mg).

7. The LED chip as claimed in claim 1, wherein a thickness of the first sublayer is greater than that of the second sublayer, the part of the upper surface of the first sublayer around the second sublayer is a roughened surface, and a roughness of the roughened surface is in a range of 0.1 μm to 1 μm; and the upper surface of the second sublayer is flatter than that of the first sublayer.

8. The LED chip as claimed in claim 1, wherein a doping concentration of the first sublayer is in a range of 1E17 atomic numbers per cubic meter (atoms/cm³) to 5E18 atoms/cm³.

9. The LED chip as claimed in claim 1, wherein a doping concentration of the second sublayer is at least 1E19 atoms/cm³, and a doping element of the second sublayer is carbon (C).

10. The LED chip as claimed in claim 1, wherein the second sublayer comprises a plurality of independent protrusion structures formed on the first sublayer.

11. The LED chip as claimed in claim 10, wherein the plurality of protrusion structures are arranged in an array, and a width of an upper surface of each protrusion structure is smaller than a distance between adjacent two of the plurality of protrusion structures.

12. The LED chip as claimed in claim 11, wherein the upper surface of each protrusion structure is parallel to the upper surface of the first sublayer, each protrusion structure further comprises a side wall connected between the upper surface of the protrusion structure and the upper surface of the first sublayer, and the side wall is inclined relative to the upper surface of the protrusion structure at an inclination angle of 120-150 degrees (°).

13. The LED chip as claimed in claim 10, wherein a ratio of a sum of horizontal projection areas of upper surfaces of the plurality of protrusion structures to a horizontal projection area of the first sublayer is in a range of 5% to 30%.

14. The LED chip as claimed in claim 1, wherein the second sublayer comprises a net structure formed on the first sublayer.

15. The LED chip as claimed in claim 14, wherein a ratio of a horizontal projection area of an upper surface of the net structure to a horizontal projection area of the first sublayer is in a range of 5% to 30%.

16. The LED chip as claimed in claim 1, wherein the second sublayer comprises a plurality of strip structures parallel to one another, formed on the first sublayer.

17. The LED chip as claimed in claim 16, wherein a ratio of a sum of horizontal projection areas of upper surfaces of the plurality of strip structures to a horizontal projection area of the first sublayer is in a range of 5% to 30%.

18. The LED chip as claimed in claim 1, wherein the second semiconductor layer further comprises a hole injection layer disposed on a side of the first sublayer facing away from the second sublayer; and a material of the hole injection layer is the same as that of the first sublayer.

19. The LED chip as claimed in claim 1, wherein the LED chip further comprises a first electrode and a second electrode, the first electrode is in contact with the first semiconductor layer, and the second electrode is in contact with the transparent conductive layer.

20. A light-emitting device, comprising a substrate and the LED chip as claimed in claim 1 disposed on the substrate.
